(19) United States
(12) Patent Application Publication
(10) Pub. No.: US 2026/0358701 A1
(43) Pub. Date: Nov. 12, 2026

(54) Continuous Roll-to-Roll Fabrication of Chi-Lattice Metamaterial Energy-Harvesting Sheets

(71) Applicant: Jonathan Washburn, Austin, TX (US)

(72) Inventor: Jonathan Washburn, Austin, TX (US)

(21) Appl. No.: 19/672,162

(22) Filed: May 8, 2026

Related U.S. Application Data
(60) Provisional application No. 63/804,586, filed on May 12, 2025.

(51) Int. Cl. G03F 7/00; G03F 7/16; G03F 7/20

(52) U.S. Cl. CPC G03F 7/0002; G03F 7/16; G03F 7/20

(57) ABSTRACT

A method, apparatus, and system for continuous roll-to-roll fabrication of chi-lattice metamaterial sheets are disclosed. A phi-governed hierarchical pattern is transferred onto a moving web in a single press cycle using a nanoimprint stamp defining at least three nested relief depths corresponding to a base pitch, a second pitch equal to the base pitch divided by phi, and a third pitch equal to the base pitch divided by phi squared. First and second interpenetrating phases are formed at a volumetric ratio equal to phi. Paired counter-helical recognition paths are formed at an angular offset of phi divided by pi. Energy-harvesting elements may be integrated at phi-lattice nodes. Inline metrology measures structural state of the web and provides feedback for process correction, enabling scalable manufacture of chi-lattice metamaterial sheets with controlled structural fidelity.

### CROSS-REFERENCE TO RELATED APPLICATIONS

This application claims the benefit of and priority to U.S. Provisional Patent Application No. 63/804,586, filed on May 12, 2025, and titled “Continuous Roll to Roll Nanoimprint Fabrication of Chi-Lattice Metamaterial Energy Harvesting Patterns,” the entirety of which is hereby incorporated by reference herein for all purposes.

### BACKGROUND

The present disclosure relates generally to manufacturing methods for metamaterial structures and, more particularly, to continuous roll-to-roll nanoimprint fabrication of χ-lattice metamaterial sheets having φ-governed hierarchical geometry, counter-helical recognition-path structures, and integrated energy-harvesting functionality.

Metamaterial devices intended to interact with ambient thermal, phononic, electromagnetic, or coherence-related phenomena often require patterned architectures having sub-micron features, multiple hierarchical pitch scales, and precise spatial relationships maintained over large areas. In many cases, the practical usefulness of such devices depends not only on whether the target geometry can be formed at laboratory scale, but also on whether that geometry can be reproduced continuously, economically, and with sufficiently tight process control to preserve the intended functional behavior across extended web lengths.

Existing fabrication approaches present substantial limitations in this regard. Serial write techniques, including high-resolution direct-write and two-photon fabrication approaches, can provide fine feature definition but generally do so at throughput and cost levels that are poorly suited for meter-scale deployment. Wafer-based lithographic approaches can improve dimensional control in localized areas, but they commonly require multiple exposures, multiple etch or transfer stages, and stitching between fields, which can introduce cumulative registration error, pitch mismatch, and process complexity. Conventional nanoimprint methods can offer higher throughput, but they are typically optimized for single-depth or single-level transfer and therefore do not readily support efficient formation of a multilevel hierarchical pattern in one press cycle.

Roll-to-roll coating and pattern-transfer systems also present unresolved problems when used for advanced metamaterial structures. Uniform film-deposition lines can produce large-area coatings, but they do not by themselves create the precise hierarchical topography, dual-phase volumetric organization, or paired counter-helical path geometries required for more advanced χ-lattice structures. Similarly, known high-throughput web processes generally do not integrate, in a single coordinated production line, the pattern transfer, dual-material phase formation, path definition, harvester integration, and phase-quality monitoring needed to produce a functionally complete χ-lattice metamaterial sheet at commercial scale.

Additional limitations arise where the functional performance of the resulting sheet depends on maintaining specific structural relationships rather than merely reproducing a decorative or arbitrary surface pattern. For example, where a hierarchical lattice relies on a defined pitch relationship across multiple levels, a defined volumetric relationship between interpenetrating phases, and a defined angular relationship between paired conductive or recognition paths, departures from those relationships can degrade the intended response of the sheet. In such contexts, process drift, nonuniform pressure, thermal expansion, coating variation, and registration error can materially impair performance unless detected and corrected during fabrication.

A need therefore exists for a scalable fabrication architecture capable of producing χ-lattice metamaterial sheets continuously on a moving web while preserving the load-bearing geometric relationships of the lattice, including hierarchical pitch relationships, dual-phase volumetric relationships, and counter-helical path relationships, and while further enabling inline integration of energy-harvesting structures and process-feedback control. A further need exists for such an architecture to reduce cost and complexity relative to serial or multi-step fabrication methods while maintaining manufacturable fidelity over large-area output.

The present disclosure addresses these and other deficiencies by providing a continuous roll-to-roll fabrication platform in which a φ-governed multilevel pattern may be transferred in a single press cycle, phase-forming materials may be established in a controlled relationship, counter-helical path structures may be defined inline, and metrology-driven process correction may be applied during production so that the resulting χ-lattice sheet may be manufactured at useful scale with controlled structural fidelity.

### SUMMARY

The present disclosure provides a continuous roll-to-roll fabrication architecture for producing χ-lattice metamaterial sheets in which a φ-governed hierarchical pattern is transferred and completed inline so that the resulting sheet exhibits large-area manufacturability together with ambient-energy harvesting capability and decoherence-suppressing structural behavior.

In one aspect, the disclosure provides a roll-to-roll method of fabricating a χ-lattice metamaterial sheet. The method includes imprinting a hierarchical φ-cascade onto a moving web in a single press cycle using a stamp carrying at least three nested relief depths corresponding to pitches P, P/φ, and P/φ². The method further includes forming first and second interpenetrating material phases on the patterned web such that the volumetric ratio of the phases is φ, forming paired counter-helical recognition paths in or on the patterned structure at an angular offset of φ/π, and performing inline metrology on the web while adjusting one or more process parameters based on the measured phase state.

In another aspect, the disclosure provides a nanoimprint stamp or imprint roller configured for roll-to-roll transfer of a χ-lattice hierarchical pattern. In certain implementations, the stamp carries at least three nested relief depths encoding a φ-pitch cascade, and may further include a pressure-equalization micro-channel network, a thermo-elastic compensation structure, and a release surface configured to improve transfer fidelity over repeated imprint cycles.

In another aspect, the disclosure provides a roll-to-roll fabrication system including web handling, a φ-cascade imprint station, a phase-formation station for establishing dual interpenetrating phases in a controlled volumetric relationship, a counter-helix patterning station, an energy-harvester integration station, and an inline metrology station configured to provide feedback to one or more fabrication stations.

In another aspect, the disclosure provides a χ-lattice metamaterial sheet produced by the foregoing methods and systems. In certain embodiments, the sheet includes a triply periodic framework, first and second interpenetrating phases arranged at a volumetric ratio equal to φ, and paired counter-helical paths offset by φ/π so as to support first-order decoherence-cancellation behavior. In further embodiments, the sheet may additionally include integrated energy-harvesting elements positioned at lattice nodes or otherwise coupled to the χ-lattice architecture.

In certain preferred embodiments, the hierarchical χ-lattice is formed using a three-level φ-cascade transferred in a single press cycle, with dual-phase conformal coating performed using atomic-layer deposition or other controlled coating techniques, and with counter-helical path definition performed using mask-less digital lithography. In further preferred embodiments, inline metrology includes phase-sensitive measurement across the width of the moving web together with feedback control for pressure, exposure, deposition, or other process variables.

In certain optional embodiments, the fabricated sheet may include piezoelectric harvesting structures, inductive harvesting structures, rectification circuitry, watchdog or monitoring circuitry, protective overcoats, or alternative substrate and coating combinations. Such features may enhance performance, integration, or application-specific suitability without altering the core fabrication identity of the invention.

In certain downstream embodiments, the fabricated χ-lattice sheets may be incorporated into building skins, self-powered sensing sheets, package liners, or other assemblies. Such downstream products remain subordinate to the core invention, which resides in the roll-to-roll fabrication architecture, the load-bearing φ-governed lattice relationships, and the integrated production-line formation of the resulting χ-lattice metamaterial sheet.

The disclosure therefore provides a manufacturing platform that preserves strong structural control over a χ-lattice metamaterial during continuous production, reduces reliance on serial or multi-step fabrication approaches, and enables scalable formation of functionally complete χ-lattice sheets with integrated process fidelity control.

The common inventive concept across the disclosed method, stamp, system, and resulting sheet is the coordinated roll-to-roll fabrication kernel including (i) single-press transfer of a multilevel phi-cascade, (ii) formation of interpenetrating phases at volumetric ratio phi, (iii) formation of paired counter-helical paths at offset phi/pi, and (iv) inline metrology with feedback control that preserves these load-bearing relations during continuous production.

### BRIEF DESCRIPTION OF THE FIGURES

FIG. 1 is a schematic process-flow diagram of an example roll-to-roll fabrication line for producing a chi-lattice metamaterial sheet, showing web movement from an unwind station through cleaning, imprint, phase-formation, counter-helix patterning, energy-harvester integration, inline metrology, optional overcoat, and rewind.

FIG. 2 is a schematic cross-sectional view of an example phi-cascade nanoimprint stamp or imprint roller showing multiple nested relief depths corresponding to hierarchical pitches P, P/phi, and P/phi\hat{ }2, together with example pressure-equalization and thermal-compensation features.

FIG. 3 is a schematic representation of an example chi-lattice unit cell showing a triply periodic framework, first and second interpenetrating phases, and paired counter-helical recognition paths arranged at an angular offset of phi/pi.

FIG. 4 is a schematic representation of an example chi-lattice energy-harvesting integration architecture showing harvesting elements disposed relative to the lattice structure and, in certain embodiments, associated rectification and monitoring circuitry.

FIG. 5 is a schematic comparative diagram illustrating example production-scale and cost relationships associated with the disclosed roll-to-roll fabrication architecture relative to selected alternative fabrication approaches.

FIG. 6 is a block diagram of an example computing device configured to implement the machine-learning correction engine and fabrication-description generation functions described herein.

### DETAILED DESCRIPTION

The present disclosure provides a continuous roll-to-roll fabrication architecture for producing chi-lattice metamaterial sheets in which a phi-governed hierarchical pattern is transferred and completed inline on a moving web. The disclosed architecture is organized to preserve the load-bearing structural relationships of the chi-lattice during high-throughput manufacture, including the hierarchical pitch relationship across multiple pattern levels, the volumetric relationship between interpenetrating phases, and the angular relationship between paired counter-helical paths.

In the disclosed implementations, the invention is centered on a fabrication kernel that includes: (1) single-press transfer of a multilevel phi-cascade pattern, (2) formation of first and second interpenetrating phases in a volumetric ratio equal to phi, (3) formation of paired counter-helical recognition paths at an angular offset of phi/pi, and (4) inline metrology with feedback control.

These features may be implemented together in a coordinated production line so that the resulting chi-lattice sheet is manufactured continuously while preserving the structural relationships on which its intended functionality depends.

As used herein, “chi-lattice” refers to a metamaterial architecture having a hierarchical and spatially repeated structural organization in which a patterned framework, dual interpenetrating phases, and paired counter-helical paths are arranged according to phi-governed geometric relationships. In certain embodiments, the chi-lattice comprises a triply periodic framework derived from a Schwarz P minimal surface defined by f(x,y,z)=cos x+cos y+cos z=0, offset by delta such that the first and second interpenetrating phases occupy a volumetric ratio Vol_A/Vol_B equal to phi. In other embodiments, equivalent triply periodic or functionally corresponding frameworks may be used, provided that the load-bearing phi-governed relationships described herein are preserved.

As used herein, “phi” refers to the golden ratio, namely (1+sqrt(5))/2. In the disclosed architecture, phi is used as a determinative structural constant for multiple relationships within the fabrication design, including, by way of example, the pitch ratio between hierarchical levels, the volumetric ratio between first and second interpenetrating phases, and the angular offset relationship used for paired counter-helical paths. Where the disclosure identifies a structural relation as equal to phi or derived from phi, such relation is presented as a load-bearing relation of the disclosed design architecture rather than a merely decorative proportion.

As used herein, “phi-cascade” refers to a hierarchical pattern set including at least three pitch levels related by successive division by phi. In certain embodiments, a base pitch P0 is accompanied by a second pitch P1=P0/phi and a third pitch P2=P0/phi\hat{ }2. In certain preferred implementations, all such levels are transferred to the substrate-facing material stack in a single press cycle, rather than through multiple exposures, multiple patterning cycles, or multiple alignment-dependent transfer operations. In certain examples, the base pitch may be about 1.5 um, the second pitch may be about 0.927 um, and the third pitch may be about 0.573 um.

As used herein, “recognition paths” refers to physical functional paths, traces, channels, patterned regions, or equivalent formed structures disposed in, on, through, or relative to the chi-lattice architecture and configured to support the disclosed paired counter-helical relation and associated functional behavior. In certain embodiments, the recognition paths comprise conductive traces, deposited lines, embedded channels, patterned films, superconductive regions, or other physically realized path structures.

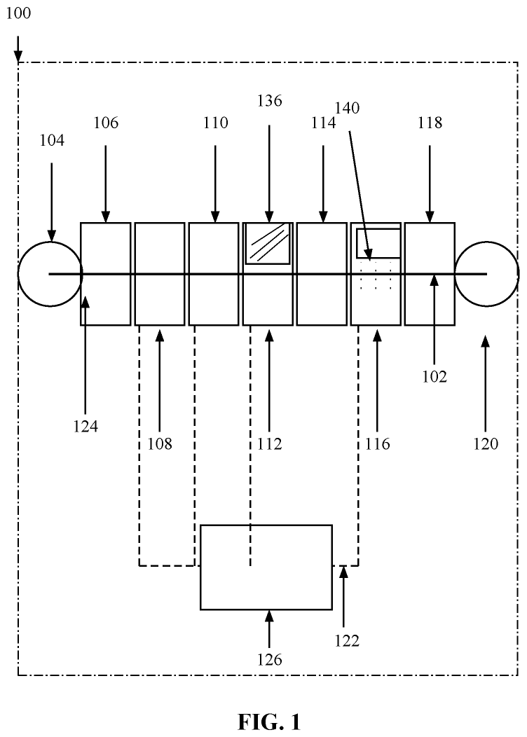

FIG. 1 illustrates an example roll-to-roll process line 100. A moving web 102 is advanced from an unwind section 104 through one or more preprocessing stages and then through a sequence of fabrication stations. In one example arrangement, the moving web 102 passes through a cleaning or preparation section 106, an imprint section 108, a phase-formation section 110, a counter-helix patterning section 112, an energy-harvester integration section 114, an inline metrology section 116, and, optionally, an overcoat or finishing section 118 before reaching a rewind section 120. The stations may be physically separated, partially merged, or otherwise arranged so long as the line carries out the fabrication kernel described herein.

The moving web may comprise a flexible polymer substrate, a semi-rigid web, a glass-bearing web, or another carrier suitable for patterned transfer and subsequent processing. In certain embodiments, the substrate may include PET or PEN. In other embodiments, the web may comprise a glass or glass-supported material. Substrate thickness, thermal tolerance, web tension, and transport speed may be selected based on the chosen processing conditions, provided that the substrate remains compatible with the pressure, temperature, coating, and exposure conditions of the line.

In certain embodiments, the web comprises PET or PEN having a thickness between about 50 um and about 125 um. In certain embodiments, web width may range from about 300 mm to about 1000 mm, and web speed may range from about 1 m/min to about 10 m/min depending on the station conditions. In certain embodiments, tension control may be maintained within about plus or minus 0.1 N/m and lateral wander may be maintained below about 1 um using an edge-tracking system. In certain embodiments, the line may operate in an ISO 6 clean-room environment at about 40 plus or minus 5 percent relative humidity with vibration isolation below about 0.5 um displacement.

Prior to imprint, the web may be cleaned, activated, planarized, primed, or otherwise conditioned. In certain embodiments, a plasma clean, solvent clean, particulate-removal process, adhesion-promoting treatment, or surface-energy adjustment may be used. A curable resist or transferable pattern-forming layer may then be applied to the web. In certain embodiments, the layer may be applied by slot-die coating, gravure, meniscus coating, or another web-compatible application process.

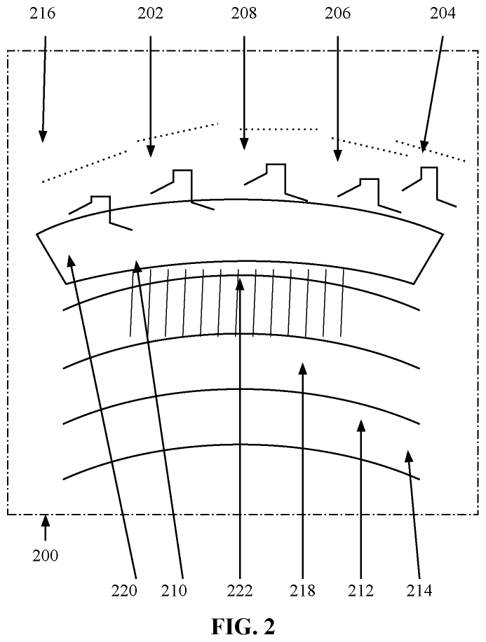

FIG. 2 shows, in greater detail, an example nanoimprint stamp or imprint roller 200 suitable for use in the imprint section 108. The stamp 200 includes a pattern-bearing working surface 202 having multiple nested relief levels. In certain embodiments, a first relief depth 204 corresponds to the base pitch P, a second relief depth 206 corresponds to P divided by phi, and a third relief depth 208 corresponds to P divided by phi squared. In certain examples, the three relief depths are about 80 nanometers, about 50 nanometers, and about 31 nanometers, respectively. Although three levels are shown and presently preferred, additional subordinate or superordinate levels may be used in certain embodiments, provided that the disclosed three-level relation remains present as the load-bearing transfer structure.

The stamp 200 may be formed as a flat stamp, curved stamp, cylindrical shell, roller, sleeve, or other transfer article. In certain preferred embodiments, the stamp 200 is configured as a cylindrical imprint roller suitable for continuous roll-to-roll use. In certain embodiments, the stamp body or core 222 may comprise fused quartz, electroformed nickel, or another durable pattern-bearing material capable of maintaining relief fidelity over repeated use.

In certain preferred embodiments, the stamp 200 further includes a pressure-equalization structure 210. For example, a buried or embedded micro-channel network 210 may be formed within or adjacent the stamp body 222 to reduce pressure nonuniformity across the width of the moving web 102 and across the nip region. In certain embodiments, the micro-channel network 210 comprises a buried rectilinear grid on about 15 millimeter centres. In a multilevel transfer process, local pressure variation can disproportionately affect shallow or fine-relief features, and therefore pressure equalization can contribute materially to preserving fidelity of the smaller pitch levels.

FIG. 2 also represents a thermo-elastic compensation structure 212 associated with the stamp 200.

In certain embodiments, the compensation structure 212 comprises an Invar frame or compensation frame 214, ring, reinforcement member, or other low-expansion support coupled to the perimeter or body of the stamp 200. In certain embodiments, the compensation structure 212 has a coefficient of thermal expansion not greater than about 0.2 parts per million per Kelvin. The purpose of such a feature is to reduce dimensional drift arising from temperature changes associated with line operation, curing, coating, or environmental fluctuation.

In certain embodiments, the working surface 202 of the stamp 200 may include a release surface treatment 216, such as a fluorinated surface treatment, monolayer release coating, perfluoropolyether-based release layer, or other low-adhesion surface conditioning. In certain preferred embodiments, the release surface treatment 216 comprises a perfluoropolyether monolayer having a release energy not greater than about 5 millijoules per square meter. Such release conditioning may facilitate separation between the patterned web 102 and the stamp 200 after curing or transfer, and may improve usable cycle life over repeated imprint operations.

In certain embodiments, the stamp is configured to provide pitch fidelity within about plus or minus 0.3 percent across a span of about 300 mm, pressure uniformity within about plus or minus 2 percent via the micro-channel network, overlay accuracy within about plus or minus 100 nm with optical alignment, operating temperature up to about 80 degrees C, and cycle life greater than about 5,000 imprints before refurbishment. In certain roll-format embodiments, the stamp is electroformed onto a cylindrical mandrel and bonded to a carbon-fibre shell to provide a compliant imprint roller carrying the full phi-cascade pattern around its circumference.

In one preferred stamp architecture, the stamp 200 comprises a core 222 of about 2 millimeters to about 5 millimeters fused quartz or electroformed nickel, a working surface 202 carrying a first relief depth 204, a second relief depth 206, and a third relief depth 208 encoding the full phi-cascade P, P divided by phi, and P divided by phi squared, a pressure-equalization structure 210 arranged as a buried rectilinear micro-channel grid on about 15 millimeter centres, a thermo-elastic compensation structure 212 including an Invar frame 214 bonded to the periphery and having coefficient of thermal expansion not greater than about 0.2 parts per million per Kelvin, and a release surface treatment 216 having release energy not greater than about 5 millijoules per square meter. In certain roll-to-roll embodiments, the stamp 200 is electroformed onto a cylindrical mandrel 218 and bonded to a carbon-fiber shell 220 to define a compliant imprint roller carrying the full phi-cascade pattern around its circumference.

During imprint, the web and stamp are brought into patterned transfer contact at a nip region or equivalent transfer interface. In certain embodiments, a UV-curable resist is applied by slot-die coating at a thickness between about 200 nm and about 500 nm before imprint. In certain embodiments, pressure is applied between about 2 bar and about 5 bar. In certain embodiments, UV exposure at about 365 nm and about 500 mJ/cm\hat{ }2 is delivered through a transparent quartz stamp body while the pattern-transfer layer remains in conformal contact with the patterned tool. In certain embodiments, the web separates from the stamp at the nip point while retaining the transferred three-level phi-cascade topography.

A significant aspect of the disclosed architecture is that the hierarchical pitch set is transferred in a single press cycle. This single-press transfer reduces or eliminates the need for sequential alignment-sensitive exposures or multiple imprint cycles for each pitch level. As a result, the process may reduce cumulative registration error, reduce field-to-field mismatch, simplify tooling logic, and preserve the exact relative positioning of the multilevel phi-cascade.

After imprint and separation, the patterned web may be subjected to a post-exposure bake, cross-linking stage, densification stage, or stabilization stage before downstream processing. In certain embodiments, a post-exposure bake is performed at about 80 degrees C for about 30 seconds. In certain embodiments, residual layer thickness is maintained below about 20 nm and line speed through the imprint station is maintained between about 2 m/min and about 5 m/min. Such stabilization and control may improve dimensional retention during subsequent coating or patterning operations.

For clarity of enablement, the roll-to-roll fabrication line 100 may be understood as comprising five coordinated fabrication stations: Station 1, imprint and transfer at section 108; Station 2, dual-phase conformal coating at section 110; Station 3, counter-helix patterning at section 112; Station 4, energy-harvester integration at section 114; and Station 5, inline metrology and feedback at section 116. In preferred implementations, these stations are operated as an integrated production line so that the load-bearing structural relations of the chi-lattice sheet are formed and preserved inline rather than reconstructed through separate offline steps.

In one preferred Station 1 implementation, the moving web passes over a compliant backing roller, a UV-curable resist is applied by slot-die coating at a thickness between about 200 nm and about 500 nm, and a phi-cascade imprint roller presses against the web at a controlled pressure between about 2 bar and about 5 bar so as to transfer all three relief levels simultaneously. In certain embodiments, UV exposure at about 365 nm and about 500 mJ/cm\hat{ }2 is delivered through a quartz stamp while the resist remains in contact with the patterned surface, after which the web separates from the stamp at the nip point retaining the three-level phi-cascade topography. In certain embodiments, a post-exposure bake at about 80 degrees C for about 30 seconds cross-links the resist for downstream processing. In certain examples, resist thickness uniformity is maintained within about plus or minus 5 percent, imprint pressure uniformity within about plus or minus 2 percent, UV dose uniformity within about plus or minus 3 percent, residual layer thickness below about 20 nm, and line speed through Station 1 between about 2 m/min and about 5 m/min.

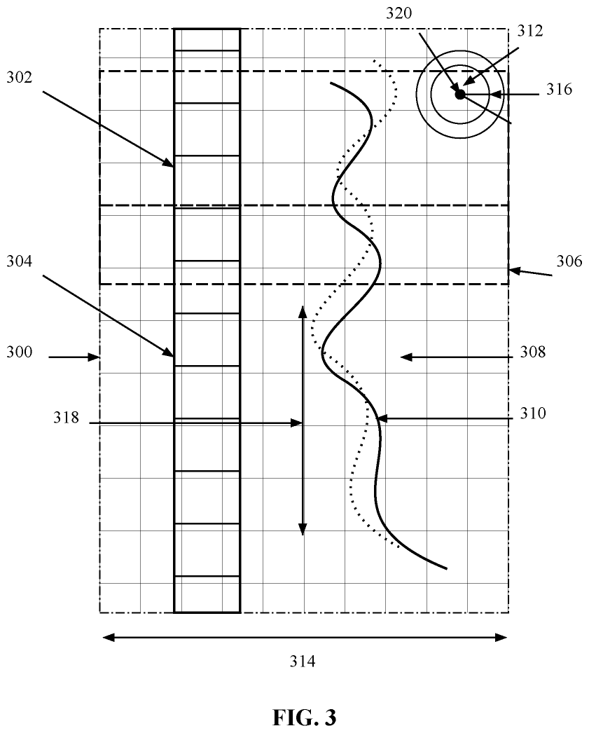

FIG. 3 illustrates an example chi-lattice unit cell 300. In certain embodiments, the unit cell 300 includes a triply periodic framework 302 defining first and second interpenetrating regions or phases 304 and 306. In the disclosed architecture, the first and second phases 304 and 306 are established so that their volumetric ratio is equal to phi. In certain implementations, this ratio may be established through a combination of template geometry and coating control rather than template geometry alone.

In certain embodiments, the chi-lattice unit cell has a lattice constant a between about 0.5 um and about 5 um, wall thickness t between about 100 nm and about 300 nm, helix radius r equal to about 0.1a, and minimum feature sizes down to about 100 nm. These values are illustrative of a preferred implementation range and provide additional support for manufacturable realization of the disclosed geometry.

The phase-formation section of FIG. 1 may be configured to form the two interpenetrating phases by conformal deposition onto the imprinted structure. In certain preferred embodiments, spatial atomic-layer deposition is employed because it permits precise thickness control in a moving-web environment while providing good conformity over structured surfaces. In one preferred implementation, a first phase comprising HfO2 is deposited using TDMA-Hf and H2O precursors for about 250 cycles at about 250 degrees C to produce about 25 nm conformal thickness at a growth rate of about 1 A/cycle, and a second phase comprising SiO2 is deposited using TEOS and O3 precursors for about 200 cycles at about 200 degrees C to produce about 20 nm conformal thickness at a growth rate of about 1 A/cycle.

In certain preferred embodiments, the first and second phases are formed from HfO2 and SiO2. In other embodiments, TiO2 and AlN may be used. Additional material pairs may also be used so long as the resulting interpenetrating phase architecture preserves the volumetric ratio equal to phi and remains compatible with the intended patterned, electromagnetic, mechanical, or thermal functionality of the chi-lattice sheet.

The volumetric ratio equal to phi may be achieved through control of layer thickness, coverage, template geometry, deposition cycle count, sidewall conformality, fill fraction, or combinations thereof. In certain embodiments, the ratio may be evaluated according to Vol_A/Vol_B=(thickness_A×coverage_A)/(thickness_B×coverage_B), with a target ratio equal to phi. In certain embodiments, metrology may infer or directly estimate the phase ratio using optical, ellipsometric, refractive-index-based, or diffraction-based measurements. In certain preferred implementations, process feedback is applied so that the phase ratio remains within a controlled tolerance band around the target ratio equal to phi.

In one preferred Station 2 implementation, Phase A deposition comprises spatial atomic-layer deposition of HfO2 using TDMA-Hf and H2O precursors for about 250 cycles at about 250 degrees C to produce about 25 nm conformal thickness on sidewalls at a growth rate of about 1 A/cycle, and Phase B deposition comprises spatial atomic-layer deposition of SiO2 using TEOS and O3 precursors for about 200 cycles at about 200 degrees C to produce about 20 nm conformal thickness at about 1 A/cycle. In certain embodiments, the volume-ratio check is expressed as Vol_A/Vol_B=(25 nm×coverage_A)/(20 nm×coverage_B), with target Vol_A/Vol_B equal to phi, controlled by cycle-count ratio and template geometry. In an alternative implementation, slot-die or inkjet deposition of TiO2 and AlN nanoparticle inks is followed by pulsed-energy densification, including xenon-flash or microwave-burst densification, to provide higher throughput at reduced conformality.

FIG. 3 further illustrates paired counter-helical recognition paths 308 and 310 embedded in, formed on, or otherwise associated with the chi-lattice framework 302. In certain preferred embodiments, the paths 308 and 310 are embedded within the framework 302 and each follows a helix having radius 316 equal to about 0.1a and pitch 318 equal to phi times lattice constant 314. The paired paths 308 and 310 are angularly separated by an angular offset 312 equal to phi divided by pi, which is approximately 0.515 radians or approximately 29.5 degrees. In certain embodiments, the paths 308 and 310 may be conductive, semi-conductive, superconductive, optical, or otherwise responsive paths formed by lithographic, deposition, lift-off, or pattern-transfer techniques.

In FIG. 3, numeral 320 identifies a reference feature used to illustrate the relative positioning of the angular-offset region for the paired counter-helical paths, and is provided for diagrammatic clarity.

A significant structural feature of the paths 308 and 310 of FIG. 3 is that they are counter-helical and angularly offset by phi divided by pi at offset 312. In the disclosed architecture, this angular relation is used as the determinative relation associated with the intended first-order decoherence-cancellation behavior. In certain implementations, for an external perturbation P(r,t), the line integrals along the paired paths 308 and 310 satisfy a cancellation relation that zeroes the first-order decoherence integral.

In certain implementations, the paired counter-helical geometry is selected such that, for an external perturbation P(r,t), the line integrals along the two paths satisfy the relation [symbol] _path1 P·dl+ [symbol] _path2 P·dl=0, thereby zeroing the first-order decoherence integral. In certain examples, this first-order cancellation condition is asserted across a broadband range from about 10 kHz to about 10 THz and at temperatures up to about 350 K.

Formation of the counter-helical paths 308 and 310 may be performed by a dedicated patterning station, such as the counter-helix patterning section 112 represented in FIG. 1. In certain preferred embodiments, the patterning section 112 uses a mask-less digital lithography approach, such as a digital-light-processing bar 136, programmable exposure head, scanned optical projection system, or other digitally addressable patterning device synchronized with web motion. In certain embodiments, the station uses a pixel pitch of about 1 micrometer, grayscale depth of about 8 bits, an exposure wavelength of about 405 nanometers, and encoder synchronization within about plus or minus 50 nanometers relative to web motion.

After exposure and development of a path-defining resist or imageable layer, a conductive or otherwise functional material may be deposited and patterned to define the paths 308 and 310. In certain embodiments, metallization includes a thin titanium/gold stack comprising about 5 nanometers titanium and about 20 nanometers gold. In certain embodiments, about 25 nanometers niobium nitride or another superconducting or low-loss material is used.

In one preferred Station 3 implementation, a mask-less digital-light-processing bar writes the counter-helical recognition-path pattern onto a second resist layer, with two interleaved helices per unit cell, helix radius r=0.1a, angular offset phi/pi, and pitch p=phi×a. In certain embodiments, the DLP system has about 1 um pixel pitch, about 8-bit grayscale depth, about 405 nm wavelength, real-time bitmap streaming from a design file, and encoder synchronization within about plus or minus 50 nm relative to web motion. After DLP exposure and development, a conductive layer comprising about 5 nm Ti and about 20 nm Au, or alternatively about 25 nm NbN for superconducting variants, may be deposited and lifted off to define the paired counter-helical paths.

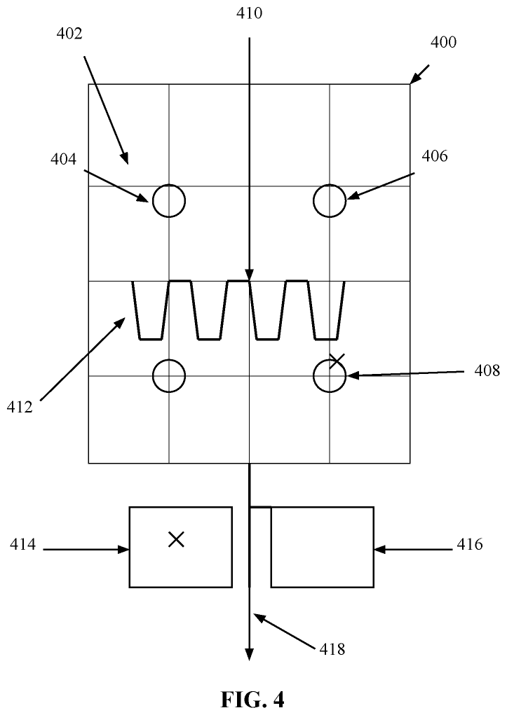

FIG. 4 illustrates an example energy-harvesting integration architecture 400. In certain embodiments, energy-harvesting structures are positioned at or relative to chi-lattice nodes 404, cells, or pathway regions of a chi-lattice framework or sheet region 402. In certain preferred embodiments, piezoelectric structures 406 are positioned at phi-lattice nodes 404 to capture phononic, vibrational, or related ambient inputs. In certain preferred embodiments, inductive or meander-type structures 410 are also integrated to capture a second band or mode of ambient input.

In one preferred embodiment, piezoelectric harvesting structures 406 include aluminum nitride trampoline membranes 408 positioned at phi-lattice nodes 404. In certain embodiments, the membrane pitch matches the Level 0 phi-cascade pitch, the piezoelectric coefficient is about five picocoulombs per newton, the operating capture band is about 2 terahertz to about 6 terahertz, and the quality factor is greater than about 1000. In another preferred embodiment, inductive harvesting structures 410 include niobium nitride meander inductors 412 tuned to about 20.1 kilohertz and impedance matched to about 50 ohms.

In certain embodiments, the line may further integrate rectification or power-conditioning circuitry.

By way of example, a switched-capacitor rectifier 414 having a phi-ratio switching architecture may be formed, printed, deposited, or otherwise coupled to the fabricated sheet region 402. In certain embodiments, the switching ratio is equal to phi and is associated with Fibonacci self-similar charge redistribution. In further embodiments, a watchdog circuit 416 may be provided to disconnect, isolate, or alter operation of the rectifier 414 if a prescribed imbalance criterion is detected.

The rectifier and watchdog circuitry are optional embodiments. They may improve downstream energy usability, monitoring fidelity, or application-specific integration, but they are not required to define the broadest manufacturing kernel of the invention. Likewise, overcoats, barrier layers, protective encapsulation, and printed or hybrid electronics may be included as optional subassemblies depending on end use.

In one preferred Station 4 implementation, phonon-band harvesting structures comprise piezoelectric harvesting structures 406 including aluminum nitride trampoline membranes 408 patterned at phi-lattice nodes 404, with membrane pitch matching the Level 0 phi-cascade pitch, piezoelectric coefficient of about five picocoulombs per newton, capture band from about 2 terahertz to about 6 terahertz, and quality factor greater than about 1000. In certain embodiments, coherence-ripple harvesting structures comprise inductive harvesting structures 410 including a niobium nitride meander inductor 412. In certain embodiments, a switched-capacitor rectifier 414 and a watchdog circuit 416 are integrated with the architecture 400, and output is delivered through an output path 418.

FIG. 1 further illustrates an inline metrology section 116. In the disclosed architecture, the inline metrology section 116 is used to monitor the structural state of the moving web 102 and to adjust one or more fabrication variables during line operation. This metrology-and-feedback arrangement is part of the load-bearing process architecture because the intended chi-lattice functionality depends on preserving exact or near-exact structural relationships during continuous production.

In certain embodiments, the inline metrology section 116 includes one or more ellipsometry beams, diffraction-based measurement paths, interferometric measurements, thickness measurements, optical phase measurements, or combinations thereof. In certain preferred embodiments, multiple ellipsometer beams 140 are distributed across the width of the moving web 102 to measure phase delay, film thickness, pitch fidelity, and inferred volumetric ratio at multiple transverse positions.

Data generated by the inline metrology section 116 may be communicated through a feedback path 122 to one or more upstream or downstream stations so as to adjust imprint pressure, exposure dose, coating cycle count, deposition parameters, web speed, lateral alignment, or other process variables.

In certain embodiments, the feedback path 122 is controlled in whole or in part by a machine-learning correction engine 126.

In some embodiments, the metrology station defines quality gates for pass, downgrade, rework, trim-out, splice-out, or reject decisions. In certain examples, phase error less than about 5 degrees is treated as pass, phase error between about 5 degrees and about 10 degrees is treated as secondary-use quality, and phase error greater than about 10 degrees is treated as reject. In certain examples, pitch error less than about 0.5 percent and volumetric-ratio error less than about 2 percent are treated as pass conditions, with steady-state yield greater than about 95 percent. Such thresholds may be used for manufacturing control and process accountability. Specific threshold examples disclosed herein are exemplary and do not limit the invention absent express claim language.

For purposes of the disclosed metrology and feedback control, a predetermined threshold may include an objective manufacturing acceptance criterion disclosed herein, including phase error less than about 5 degrees for pass quality, phase error between about 5 degrees and about 10 degrees for secondary-use quality, phase error greater than about 10 degrees for rejection, pitch error less than about 0.5 percent, or volumetric-ratio error less than about 2 percent. The thresholds may be selected for a fabrication recipe and applied by the inline metrology section to determine pass, downgrade, rework, trim-out, splice-out, reject, or process-adjustment actions.

In one preferred Station 5 implementation, multiple ellipsometer beams 140 in the inline metrology section 116 measure phase delay, film thickness, pitch fidelity, and volume ratio. In certain embodiments, the machine-learning correction engine 126 receives real-time phase-error maps through feedback path 122, predicts dose corrections for the patterning section 112, adjusts imprint pressure for the imprint section 108, and tunes deposition control for the phase-formation section 110. In certain examples, convergence occurs within less than about 20 centimeters of web travel so as to reduce phase error from about plus or minus 20 degrees in open loop to about plus or minus 5 degrees in closed loop.

In certain embodiments, the machine-learning correction engine 126 and/or fabrication-description generation functions (e.g., claim 24) are implemented by one or more computing devices including a processor and a memory storing instructions that, when executed by the processor, receive metrology measurements (e.g., phase-error maps), compute one or more control updates (e.g., exposure dose, imprint pressure, deposition cycle count, or patterning parameters), and output control signals and/or fabrication files to one or more stations. The computing device may further include one or more interfaces for receiving metrology data and for communicating control outputs to the fabrication line.

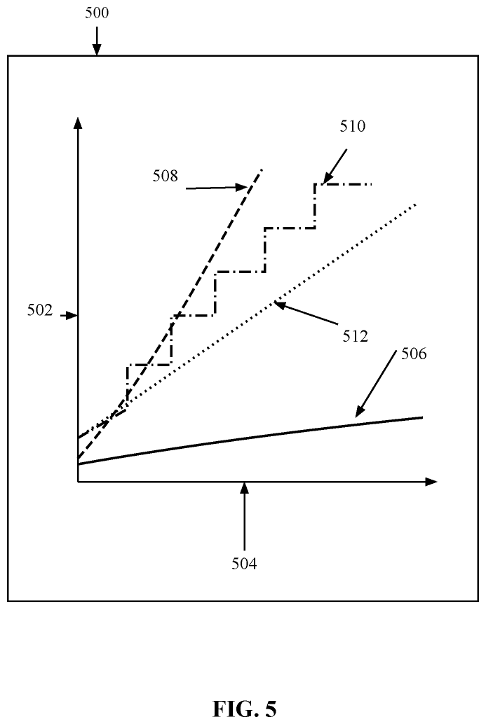

FIG. 5 illustrates a comparative production-scale and cost diagram 500. In the illustrated embodiment, a cost axis 502 is plotted relative to a production-scale or area axis 504. The disclosed roll-to-roll chi-lattice fabrication architecture 506 is shown in comparison with a serial or two-photon fabrication approach 508, a wafer-scale lithographic approach 510, and a conventional nanoimprint approach 512. The comparative diagram 500 is intended to illustrate the advantage of a continuous single-line architecture in which hierarchical transfer, phase formation, path definition, integration, and feedback control are performed inline rather than through multiple serial or separately staged manufacturing flows.

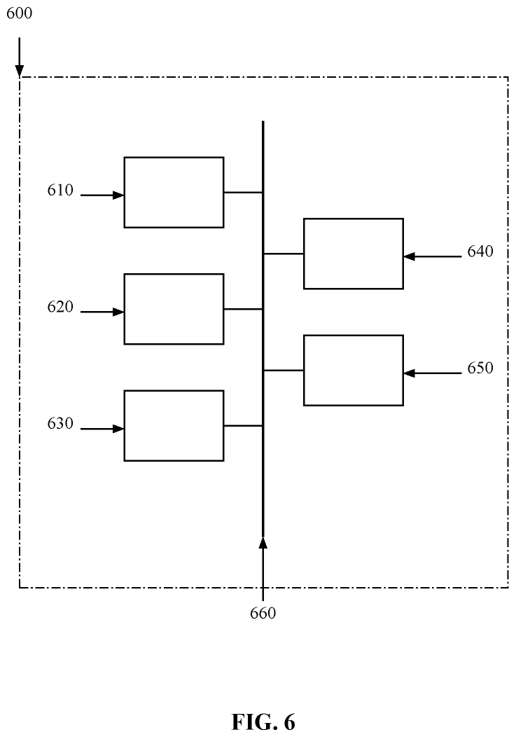

FIG. 6 illustrates an example computing device 600. In certain embodiments, the computing device 600 includes a processor 610, a memory 620 storing executable instructions, one or more interfaces 630, 640, and 650 for receiving metrology data, communicating control outputs, and/or outputting fabrication files, and a bus or communication path 660 coupling the foregoing components. The computing device 600 may implement the machine-learning correction engine 126 and/or the fabrication-description generation functions described herein.

In certain embodiments, the disclosed line produces chi-lattice sheets suitable for subsequent incorporation into building panels, self-powered sensor sheets, package liners, or other downstream articles. Such downstream products may be fabricated by cutting, laminating, packaging, connecting, or otherwise integrating the produced sheet. However, such downstream embodiments remain subordinate to the core invention, which resides in the roll-to-roll fabrication architecture and the resulting chi-lattice sheet produced according to the load-bearing structural relationships described herein.

In one downstream embodiment, the produced chi-lattice sheet may be laminated into a building or HVAC skin together with sensing, thermal-routing, or communication functionality. In another downstream embodiment, the produced sheet may be cut into smaller sections and combined with printed electronics to provide self-powered sensing nodes. In another downstream embodiment, the produced sheet may be used as a package liner, including in environments where phase stability, low added noise, or local energy availability are beneficial.

The disclosure also contemplates alternative substrates, alternative material pairs, alternative station ordering, alternative exposure systems, alternative deposition systems, and alternative integration choices, provided that the fabrication kernel is preserved. Accordingly, no individual optional material, coating modality, electronics package, or downstream application should be understood as required unless expressly stated in a claim.

In certain implementations, formal verification or machine-checked support may be used as a technical support framework for the geometric and functional relationships used in the disclosed architecture. By way of example, machine-checked support may confirm the exact phi pitch ratio, the exact phase volumetric ratio equal to phi, the path-offset relation phi/pi, first-order decoherence-cancellation conditions, phi-ratio switching optimality, ledger-neutrality support, and watchdog zero-imbalance safety support. In certain embodiments, such support corresponds to machine-checked theorems including pitch_ratio, volume_ratio_is_phi, first_order_zero, phi_ratio_optimal, ledger_neutral, and zero_imbalance_safe. Such material is provided as technical support and credibility anchor for the disclosed architecture and not as a legal conclusion.

The disclosed architecture therefore provides a disciplined, scalable fabrication platform for manufacturing chi-lattice metamaterial sheets in continuous web form while preserving the single-press phi-cascade transfer, volumetric ratio equal to phi, angular offset phi/pi, and inline metrology-and-feedback structure that define the core identity of the invention.

The disclosed architecture provides several advantages over prior fabrication approaches, including single-press transfer of a three-level phi-cascade, inline integration of dual-band harvesting structures rather than post-process assembly, closed-loop phase control using inline metrology and feedback, ledger-neutral harvesting using watchdog-protected rectification, mask-less counter-helix patterning without fixed tooling for each design variant, and mathematically verified support for the phi-pitch ratio, volume ratio, decoherence-cancellation condition, switching-ratio optimality, and watchdog balance condition.

Referring again to FIG. 1, the roll-to-roll fabrication line 100 is configured so that the moving web 102 is processed continuously through the unwind section 104, the cleaning or preparation section 106, the imprint section 108, the phase-formation section 110, the counter-helix patterning section 112, the energy-harvester integration section 114, the inline metrology section 116, the optional overcoat or finishing section 118, and the rewind section 120. In certain embodiments, the web-handling module 124 cooperates with the feedback path 122 so that operation of one or more stations may be corrected during continuous fabrication.

The unwind section may include any suitable supply roll holder, tension-control assembly, dancer mechanism, servo-driven feed arrangement, edge guide, or web-alignment subsystem sufficient to present the incoming substrate in a controlled manner to downstream stations. In certain embodiments, closed-loop tension control is used so that web stretch, wrinkling, or lateral wander is reduced during pattern-transfer and deposition operations. In certain embodiments, lateral edge tracking and steering may be used to preserve pattern registration across the width of the web.

The cleaning or preparation section may include one or more of plasma treatment, solvent cleaning, ionized-air treatment, particulate removal, surface activation, adhesion-promotion treatment, or planarization-related conditioning. Such preprocessing may improve wetting of a resist, improve adhesion of subsequently deposited materials, reduce defect density, or improve fidelity of the subsequent imprint operation.

In certain embodiments, a pattern-transfer layer is applied to the moving web before the imprint section. The pattern-transfer layer may be a UV-curable resist, thermally curable composition, hybrid-curing composition, sol-gel precursor, embossable polymer layer, or any other layer capable of receiving and retaining the hierarchical phi-cascade pattern. In certain embodiments, the layer is applied by slot-die coating in a controlled thickness range sufficient to capture the multiple relief levels of the imprint tool while limiting residual layer thickness after transfer.

The imprint section of FIG. 1 is configured to transfer, in a single press cycle, a hierarchical pattern corresponding to at least three pitch levels. This feature distinguishes the disclosed fabrication architecture from approaches requiring sequential pattern formation of multiple levels. In the disclosed line, the stamp or roller itself carries the multilevel pattern so that the relative placement of P, P/phi, and P/phi\hat{ }2 is set by the tool architecture rather than reconstructed from multiple alignment-sensitive steps.

In certain embodiments, the imprint section includes a compliant backing roller opposing the patterned imprint roller. The web, together with the applied pattern-transfer layer, passes through the nip defined between these components. Pressure, dwell, separation angle, and line speed may be controlled so that the hierarchical topography is faithfully transferred. In certain embodiments, curing radiation is applied while the pattern-transfer layer remains in conformal contact with the patterned tool, thereby reducing collapse, relaxation, or partial spring-back before the transferred structure is stabilized.

FIG. 2 shows, in greater detail, an example stamp cross section suitable for use in the imprint section. The stamp includes a pattern-bearing working surface having multiple nested relief levels.

In certain embodiments, the largest relief level corresponds to the base pitch P, the next relief level corresponds to P/phi, and the smallest relief level corresponds to P/phi\hat{ }2. Although three levels are shown and presently preferred, additional subordinate or superordinate levels may be used in certain embodiments, provided that the disclosed three-level relation remains present as the load-bearing transfer structure.

In certain embodiments, the pattern-bearing body of the stamp comprises fused quartz, permitting transmission of curing radiation through the body. In other embodiments, the body comprises electroformed nickel or another material suitable for repeated imprint cycling. In further embodiments, a cylindrical roller construction is used in which a patterned shell, sleeve, or bonded layer is carried by a roller body. The invention is not limited to any particular mechanical support construction so long as the working surface presents the required hierarchical pattern and remains sufficiently dimensionally stable during operation.

The example stamp of FIG. 2 may further include a micro-channel network for pressure equalization. Such a network may be internal, buried, partially exposed, distributed in a grid or manifold pattern, or otherwise arranged to reduce local pressure nonuniformity. In a multilevel transfer process, local pressure variation can disproportionately affect shallow or fine-relief features, and therefore pressure equalization can contribute materially to preserving fidelity of the smaller pitch levels.

FIG. 2 also represents a thermo-elastic compensation structure associated with the stamp. In certain embodiments, the compensation structure comprises an Invar frame, ring, reinforcement member, or other low-expansion support coupled to the perimeter or body of the stamp. The purpose of such a feature is to reduce dimensional drift arising from temperature changes associated with line operation, curing, coating, or environmental fluctuation. In the disclosed architecture, dimensional drift is particularly significant because the hierarchical phi-cascade and the counter-helical path relations are load-bearing features rather than arbitrary ornamentation.

In certain embodiments, the working surface of the stamp is treated with a release coating, such as a fluorinated monolayer or PFPE-based release layer, to reduce adhesion to the resist or transfer layer.

Such treatment may improve release consistency, lower defect formation at separation, and increase usable cycle life. The release treatment may be renewed, replaced, or refreshed according to maintenance intervals.

After leaving the imprint section, the patterned web carries a stabilized hierarchical structure corresponding to the transferred phi-cascade. In certain embodiments, the transferred structure includes a residual layer beneath the relief features. In such embodiments, the residual layer may be left in place, thinned, cured, etched, densified, or otherwise conditioned depending on the downstream phase-formation strategy. The invention does not require elimination of the residual layer in every case so long as downstream formation of the chi-lattice structure remains feasible.

Referring to FIG. 3, the chi-lattice unit cell may be understood as a repeating structural motif comprising a framework and first and second interpenetrating phases. In certain embodiments, the framework is triply periodic. In certain preferred embodiments, the framework is derived from a Schwarz P-type geometry or an analogous periodic surface representation. The unit cell may be repeated in one, two, or three directions according to the desired sheet architecture, and may be truncated, adapted, or surface-opened at sheet boundaries.

In the illustrated and preferred implementations, the first and second phases occupy a volumetric ratio equal to phi. This relation may be achieved by the combined effect of the imprinted geometry and the subsequent phase-formation process. In some embodiments, the geometry itself substantially determines the phase ratio. In other embodiments, the final ratio is established by deposition thickness, conformality, infill extent, cycle count, or related parameters. In either case, the ratio equal to phi is treated herein as a load-bearing structural relation of the disclosed sheet architecture.

The phase-formation section of FIG. 1 may be configured to form the two interpenetrating phases by conformal deposition onto the imprinted structure. In certain preferred embodiments, spatial atomic-layer deposition is employed because it permits precise thickness control in a moving-web environment while providing good conformity over structured surfaces. In one preferred implementation, a first oxide phase is deposited using one precursor set and a second oxide or nitride phase is deposited using another precursor set in separate but coordinated steps.

In one preferred embodiment, HfO2 is used as a first phase and SiO2 is used as a second phase. In another preferred embodiment, TiO2 and AlN are used. These material pairs are illustrative preferred embodiments and may be selected based on refractive, dielectric, piezoelectric, thermal, mechanical, or integration-related considerations. Other material pairs may also be used, including composite, doped, alloyed, laminated, or nanoparticle-derived variants, provided that the resulting formed phases preserve the intended interpenetrating relation and remain compatible with the other stations of the line.

In some embodiments, a non-ALD coating modality may be used. By way of example, slot-die deposition, inkjet deposition, aerosolized deposition, sputtering, evaporation, hybrid additive deposition, or pulsed-energy densification may be used alone or in combination. Such alternatives may provide throughput advantages, cost advantages, or material-compatibility advantages. These are optional embodiments and do not displace the core architecture.

During phase formation, process variables such as precursor dose, cycle count, reactor spacing, substrate temperature, line speed, purge timing, and surface chemistry may be controlled so that the volumetric ratio equal to phi is maintained. In certain embodiments, inferred ratio estimation may be performed using optical constants, thickness estimation, or phase-delay-based models. In other embodiments, direct structural sampling or post-line validation may supplement inline control.

FIG. 3 further illustrates paired counter-helical recognition paths. In certain embodiments, these paths are disposed within, along, through, or adjacent the framework of the chi-lattice unit cell. In certain preferred embodiments, the paths are helically arranged relative to a diagonal or other repeated direction of the unit cell. Each path may comprise a conductive or otherwise functional line, filament, deposited trace, embedded channel, patterned film, or multilayer structure.

A significant structural feature of the paths of FIG. 3 is that they are counter-helical and angularly offset by phi/pi. In the disclosed architecture, this angular relation is not merely one design option among many but instead is used as the determinative relation associated with the intended first-order decoherence-cancellation behavior. Accordingly, where the paired path structure is recited in the present disclosure as part of the chi-lattice identity, the phi/pi offset is preserved as the load-bearing offset relation.

In certain embodiments, the path geometry may further include a defined helical radius and a defined pitch relative to the lattice constant. For example, the helix radius may be selected as a fraction of the lattice constant and the helix pitch may be selected as phi times the lattice constant. Such proportions are preferred and illustrative. The invention is not limited to one absolute scale of the unit cell and may be practiced over a range of micron-scale or sub-micron-scale lattice constants, provided that the governing relations are maintained.

The counter-helix patterning section of FIG. 1 may be configured as a digital lithography station synchronized to web motion. In certain preferred embodiments, a DLP bar or equivalent mask-less projection device writes the path geometry into a second imageable layer provided on the partially fabricated web. Encoder-based synchronization may be used so that the projected geometry tracks moving-web position with sufficient precision to maintain registration to the previously transferred hierarchical pattern.

In certain embodiments, grayscale projection, binary projection, scanned-line exposure, or pixel-addressable exposure may be used. The patterning station may define a resist image subsequently used for lift-off or subtractive patterning, or may directly define a patterned curable feature. After exposure and development, a conductive or functional material may be deposited. In certain embodiments, a thin Ti/Au stack is used. In certain embodiments, NbN or another superconducting or low-loss material is used. Such material choices are preferred or optional embodiments depending on application and should not be treated as required limitations on the broadest disclosed fabrication kernel.

Referring again to FIG. 4, the energy-harvester integration section may place one or more harvesting elements relative to lattice nodes or other selected regions of the chi-lattice. In certain preferred embodiments, piezoelectric elements are positioned at node regions corresponding to a repeated pitch level of the lattice. In certain preferred embodiments, such elements comprise AlN trampoline membranes, although other piezoelectric thin films, suspended structures, diaphragms, cantilevers, or node-coupled harvesting structures may be used.

In certain embodiments, FIG. 4 also represents an inductive or meandered harvesting structure integrated into the sheet. Such a structure may be formed from a patterned conductive line or multilayer conductor and may be configured to capture an additional band or mode of ambient input. In certain preferred embodiments, a NbN meander inductor is used. However, other conductive or superconductive structures may be used.

In certain embodiments, the sheet therefore supports dual-band or multi-mode harvesting. One contribution may arise from a mechanically or phonon-coupled harvesting structure, while another may arise from an electromagnetic, inductive, or coherence-related harvesting structure. These are preferred product-side embodiments and provide useful support for dependent claims and applications, but the broadest manufacturing invention remains the integrated roll-to-roll architecture that forms the chi-lattice sheet itself.

FIG. 4 may further represent optional rectification, conditioning, or watchdog structures. In certain embodiments, the harvested output is delivered to a switched-capacitor rectifier having a phi-ratio switching arrangement. In certain embodiments, the rectifier may be synchronized or otherwise phase-aware. In certain embodiments, a watchdog circuit monitors a selected balance condition and may disconnect or alter operation when a threshold is exceeded. Such subassemblies may be formed by printing, deposition, transfer, pick-and-place integration, hybrid assembly, or other integration methods compatible with the produced sheet.

The inline metrology section of FIG. 1 is configured to measure structural or phase-related characteristics of the moving web and to provide process feedback. In certain embodiments, the metrology station measures phase delay, coating thickness, pitch fidelity, diffraction response, refractive response, or other indicators correlated to the structural integrity of the chi-lattice architecture. In certain preferred embodiments, multiple optical beams are distributed across the web width to permit transverse profile monitoring.

In certain embodiments, the metrology section is coupled to a control engine that adjusts one or more process variables in response to measured deviation. By way of example, imprint pressure may be adjusted to correct transfer fidelity, exposure dose may be adjusted to correct path definition, and deposition parameters may be adjusted to correct volumetric ratio or layer thickness. Such feedback may be direct, model-based, threshold-based, or machine-learning-assisted.

In certain preferred embodiments, a machine-learning engine receives metrology data and predicts one or more control updates for a downstream or upstream station. Such an engine may be trained on line history, structural error maps, simulated response, or empirical calibration data. The invention is not limited to a particular machine-learning architecture, and any suitable feedback logic may be used so long as it supports preservation of the structural relations of the fabricated chi-lattice sheet.

In some embodiments, the metrology station defines quality gates for pass, downgrade, rework, trim-out, splice-out, or reject decisions. These quality gates may be based on phase error, pitch deviation, ratio deviation, defect density, web uniformity, or other metrics. Such gates may be used for manufacturing control and process accountability. Specific threshold examples disclosed herein are exemplary and do not limit the invention absent express claim language.

FIG. 5 illustrates a comparative depiction of example production-scale or cost relationships. The comparative figure is intended to show that a continuous roll-to-roll line configured according to the present disclosure can reduce complexity and cost relative to serial-write or multi-stage fabrication techniques by consolidating the load-bearing formation steps into one coordinated manufacturing architecture. The figure is not intended to require any single economic threshold in order for the invention to be practiced.

In certain example implementations, the disclosed line may operate at web widths ranging from narrow pilot-scale widths to wider production widths and at speeds selected according to material chemistry and transfer requirements. Such operating values are process-tuning embodiments and may vary substantially. What remains constant is that the fabrication architecture is configured to preserve the single-press phi-cascade transfer, volumetric ratio equal to phi, angular offset phi/pi, and inline metrology-and-feedback arrangement that define the core invention identity.

In a first downstream embodiment, the produced chi-lattice sheet may be incorporated into a building panel or HVAC skin. In such an embodiment, the fabricated sheet may be laminated, bonded, or otherwise coupled to a supporting substrate or panel body. The resulting panel may include sensing electronics, communication circuitry, thermal-routing elements, or control logic.

This embodiment is downstream and does not alter the identity of the core fabrication invention.

In a second downstream embodiment, the produced sheet may be converted into discrete self-powered sensing units. For example, a longer web may be cut into smaller sections, and each section may be combined with printed or hybrid electronics to form a sensing node. Such nodes may be used in environmental monitoring, logistics, structural health monitoring, or related applications. Again, this remains a downstream application of the fabricated sheet.

In a third downstream embodiment, the sheet may be used as a package liner or interior structural layer in a device package. In certain embodiments, this may include packaging environments where low added phase disturbance, local energy availability, or patterned electromagnetic behavior is desirable. This embodiment likewise remains subordinate to the core invention.

The present disclosure further contemplates that certain aspects of the structural relations used herein may be supported by machine-checked formal verification, mathematical proofs, or equivalent computational support. In certain implementations, such support may confirm the exact relation between hierarchical pitches, the volumetric ratio equal to phi, the angular offset phi/pi, a cancellation condition associated with the paired path structure, a phi-ratio switching property, ledger-neutrality support, or a watchdog zero-imbalance safety condition. Such support is included as technical substantiation and should be understood as supporting the engineering architecture described herein.

Where exact geometric or computational relations are described as part of the chi-lattice architecture, such relations are presented as determinative engineering relations of the disclosed invention.

However, the invention is not limited to any one software environment, proof assistant, or verification environment used to analyze or support those relations. The disclosure encompasses fabrication systems and products embodying the stated relations whether or not a particular user employs formal verification tools in practice.

The examples, materials, dimensions, operating ranges, and downstream uses described herein are illustrative unless expressly stated otherwise. A person of ordinary skill in the art, having the benefit of the present disclosure, will understand that individual stations, material systems, and integration choices may be varied without departing from the invention so long as the disclosed fabrication kernel and load-bearing structural relations are preserved.

Accordingly, the present disclosure provides a full manufacturing architecture in which the chi-lattice metamaterial sheet is not merely theorized or patterned as an isolated laboratory artifact, but is instead formed through a coordinated continuous production line that preserves the exact or load-bearing relations on which the sheet depends, including single-press phi-cascade transfer, dual-phase formation at volumetric ratio equal to phi, paired counter-helical paths at angular offset phi/pi, and inline metrology with process feedback.

In certain implementations, the structural relationships used in the disclosed chi-lattice fabrication architecture are supported by formal mathematical analysis, machine-checked verification, computational validation, or combinations thereof. Such support is used herein as a technical substantiation framework for the geometric and functional relations described in the present disclosure. Such support does not itself define the legal scope of the invention, but instead provides additional engineering basis for the use of the stated load-bearing relations in the disclosed fabrication architecture.

In certain implementations, the hierarchical pitch relation of the phi-cascade is treated as exact, such that successive pitch levels satisfy the ratio P_n/P_n+1=phi. In the disclosed manufacturing architecture, this relation is embodied in the stamp or imprint roller so that the hierarchical transfer of the pattern is set by the tool geometry itself. As a result, the pitch relation is not reconstructed after the fact by separate alignment-dependent stages, but is instead transferred as an integral feature of the imprint architecture. In certain machine-checked implementations, this relation is supported by a proved pitch_ratio theorem.

In certain implementations, the relation between first and second interpenetrating phases is treated as a volumetric ratio equal to phi. This relation may be supported by geometric design of the unit cell, by deposition control, or by both. In certain machine-checked implementations, the exact ratio Vol_A/Vol_B=phi is supported by a volume_ratio_is_phi theorem. In the disclosed architecture, this ratio is preserved as a load-bearing design relation because the functional behavior of the chi-lattice sheet is associated with maintenance of that dual-phase relationship rather than mere presence of two arbitrary materials.

In certain implementations, the paired counter-helical recognition paths are arranged at an angular offset equal to phi/pi, approximately 0.515 radians or approximately 29.5 degrees. This offset is treated herein as a determinative geometric relation associated with the path pair rather than as a discretionary styling parameter. The disclosed path arrangement is selected and maintained because the intended first-order decoherence-cancellation behavior is associated with that offset relation and with the paired counter-helical geometry as a whole.

In certain implementations, the paired path geometry is associated with a first-order cancellation condition in which a perturbation contribution along one path is offset by a corresponding contribution along the other path. In certain embodiments, the relation is expressed as integral_over_path1(P·dl)+integral_over_path2(P·dl)=0, thereby zeroing the first-order decoherence integral. In certain machine-checked implementations, this cancellation condition is supported by a first_order_zero theorem. Without limiting the invention to any particular mathematical formalism, the disclosed architecture uses the paired path structure and the phi/pi offset as an engineering condition for achieving the intended first-order decoherence-cancellation behavior of the chi-lattice sheet.

In certain embodiments including rectification circuitry, a switched-capacitor architecture may be arranged using a phi-ratio switching relation. In such embodiments, the phi-ratio may be treated as an optimal switching relation for redistribution of harvested charge across multiple stages, including by virtue of the relation phi\hat{ }2=phi+1. In certain machine-checked implementations, such optimality is supported by a phi_ratio_optimal theorem. Such embodiments are optional from the standpoint of the broadest fabrication kernel, but they provide useful support for dependent claims and integrated-sheet embodiments.

In certain embodiments including a watchdog or monitoring circuit, a zero-imbalance or prescribed-balance condition may be monitored to determine whether rectification, extraction, or coupled operation should continue, disconnect, or be altered. In certain embodiments, the watchdog disconnects rectifier operation if absolute value of delta_C exceeds a threshold and remains quiescent when delta_C equals zero. In certain machine-checked implementations, such behavior is supported by ledger_neutral and zero_imbalance_safe theorems. This is an optional embodiment and may be implemented in analog, digital, mixed-signal, printed, or hybrid form.

As used herein, an imbalance condition for a watchdog or monitoring circuit may include a prescribed balance condition associated with rectification, extraction, or coupled operation. In certain embodiments, the imbalance condition includes absolute value of delta_C exceeding a threshold, and the watchdog circuit may disconnect, isolate, or alter rectifier operation when the threshold is exceeded and remain quiescent when delta_C equals zero.

In certain implementations, formal support may also be used to confirm that the disclosed relations are mutually coherent within the larger engineering architecture. By way of example, a formal support framework may be used to confirm consistency between the hierarchical pitch relation, the phase-ratio relation, the path-offset relation, the cancellation condition, the rectifier ratio relation, and the watchdog balance condition. Such support may be useful in demonstrating that the disclosed architecture is internally disciplined and not an arbitrary collection of unrelated design choices.

In certain implementations, machine-checked support is associated with formal modules defining or proving phiPitch, ThreeLevelCascade, ChiLatticeCell, volumeRatio, DecoherenceCancellation, RollToRollParams, and HarvesterSpec, together with proved results including pitch_ratio, pitch_pos, volume_ratio_is_phi, volume_ratio_gt_one, first_order_zero, production_positive, power_linear, chi_lattice_harvester_viable, phi_ratio_optimal, ledger_neutral, zero_imbalance_safe, phi_sq_eq_phi_add_one, phi_pos, and one_lt_phi. Such formalization is presented as technical substantiation for the disclosed architecture.

In certain implementations, machine-checked support is associated with formal modules including IndisputableMonolith.Applied.ChiLatticeNanoImprint, which defines phiPitch, ThreeLevelCascade, ChiLatticeCell, volumeRatio, DecoherenceCancellation, RollToRollParams, and HarvesterSpec and proves pitch_ratio, pitch_pos, volume_ratio_is_phi, volume_ratio_gt_one, first_order_zero, production_positive, power_linear, and chi_lattice_harvester_viable; IndisputableMonolith.Foundation.EightTick, which proves sum_8_phases_eq_zero and phase_eighth_power_is_one; IndisputableMonolith.Energy.DualBandHarvester, which proves phi_ratio_optimal, ledger_neutral, and zero_imbalance_safe; and IndisputableMonolith.Constants, which proves phi_sq_eq_phi_add_one, phi_pos, and one_lt_phi. Such formalization is presented as technical substantiation for the disclosed architecture.

The present disclosure does not require that a fabricator perform or reproduce any particular proof, theorem, code base, or verification workflow in order to practice the invention. Rather, the disclosed fabrication architecture may be practiced by constructing and operating a line that embodies the stated structural relations. Formal support is presented as a technical credibility anchor for the architecture and as support for the proposition that the specified relations are treated in the present disclosure as exact, load-bearing, or determinative engineering relations.

In one example fabrication implementation, a moving polymer web is unwound and cleaned, a curable pattern-transfer layer is applied, and the web is passed through an imprint nip where a phi-cascade stamp transfers three hierarchical pitch levels in a single press cycle. The transferred structure is cured and stabilized, after which first and second material phases are formed on the patterned structure in a controlled relation such that the volumetric ratio of the phases is equal to phi.

A digital patterning station then defines paired counter-helical paths at the phi/pi offset, and one or more harvesting structures are integrated before inline metrology is used to measure phase state and provide correction signals to one or more line stations. In certain embodiments, the resulting sheet produces between about 5 uW/cm\hat{ }2 and about 12 uW/cm\hat{ }2 at about 300 K while adding less than about 0.5 mrad phase noise to adjacent quantum cavities.

In one example production implementation, the line is operated continuously so that patterned chi-lattice material is produced over extended web lengths rather than as isolated laboratory samples. In one worked example, for a web width of about 300 mm, a web speed of about 3 m/min, and a yield of about 95 percent, production rate is about 0.855 m\hat{ }2/min, corresponding to about 410 m\hat{ }2 per eight-hour shift. In one worked example, with capital cost of about $2 million, operating cost of about $50/hour, and amortization over three years at 250 days/year, total daily cost is about $3,067, corresponding to an amortized cost of about $7.50/m\hat{ }2 and a total cost with materials of about $18/m\hat{ }2. Such examples illustrate the potential economic advantage of consolidating the load-bearing formation steps into a coordinated production line.

In one worked production-economics example, web width is about 300 mm, web speed is about 3 m/min, and yield is about 95 percent, such that production rate is 0.3×333 0.95=about 0.855 m\hat{ }2/min and production per eight-hour shift is about 0.855×480=about 410 m\hat{ }2. In one such example, capital cost is about $2 million, operating cost is about $50/hour, and amortization over three years at 250 days/year is about $2,667/day, yielding a total daily cost of about $3,067/day and corresponding cost of about $3,067/410=about $7.50/m\hat{ }2 amortized, or about $18/m\hat{ }2 including about $10/m\hat{ }2 materials.

In one example downstream building-panel embodiment, a section of the produced chi-lattice sheet is laminated to a support substrate or panel body for use in a building skin or HVAC-associated surface. In one worked example, a 600 mm×600 mm panel having about 90 percent active area provides about 3,240 cm\hat{ }2 of active area and about 32.4 mW of power output at about 10 uW/cm\hat{ }2, sufficient for multiple wireless sensors, a BLE transmitter, and switching logic, with remaining power available for storage. The building-panel embodiment is a downstream application of the fabricated sheet and does not alter the identity of the core fabrication invention.

In one worked HVAC-panel example, a panel of about 600 mm×600 mm having about 90 percent active area provides about 3,240 cm\hat{ }2 of active area, and at about 10 uW/cm\hat{ }2 the resulting panel power is about 32.4 mW, sufficient for multiple wireless sensors, a BLE transmitter, and heat-router switching logic, with surplus power available for storage in a thin-film supercapacitor.

In one example downstream sensing embodiment, the produced chi-lattice sheet is cut or converted into smaller sections and integrated with printed or hybrid electronics to form self-powered sensing nodes. In one worked example, a 10 m roll at 300 mm width provides about 3 m\hat{ }2 of fabricated material and can be cut into about 300 sheets of 10 cm×10 cm each. At about 3 m/min, one roll is produced in about 3.3 minutes, corresponding to about 145 rolls or about 43,500 sheets per shift. In one worked example, unit sheet cost is about $0.18 and total sensor cost including printed electronics is less than about $1.00 per unit. The sensing embodiment is likewise downstream and subordinate to the disclosed fabrication kernel.

In one worked IoT-sheet example, a 10 m roll at about 300 mm width provides about 3 m\hat{ }2 of fabricated material and can be cut into about 300 sheets of 10 cm×10 cm each. At about 3 m/min, one roll is produced in about 3.3 minutes, corresponding to about 145 rolls or about 43,500 sheets per eight-hour shift. In one such example, unit sheet cost is about $18/m\hat{ }2×0.01 m\hat{ }2=about $0.18 per sheet, and with printed electronics at about $0.50 per sheet the total unit cost is less than about $1.00.

In one example downstream package-liner embodiment, the produced chi-lattice sheet is incorporated into an enclosure, package, liner, or internal package surface associated with a device.

In certain embodiments, this includes use as a vacuum-package liner for a superconducting quantum processor, where the sheet provides first-order decoherence cancellation, local energy harvesting for monitoring or driver circuitry, and a phi-scaled cavity geometry associated with suppression of parasitic vacuum modes. In certain examples, decoherence-cancellation metrics are stated at about 99.999 percent, T2* at about 1.07 ms at 300 K, and resonator Q at about 1.4×10\hat{ }5. This embodiment is also downstream and remains separate from the core identity of the invention.

In certain example sheet implementations operated at about 300 K in still air, total power density is between about 5 uW/cm\hat{ }2 and about 12 uW/cm\hat{ }2, with phonon-band contribution of about 3 uW/cm\hat{ }2 to about 7 uW/cm\hat{ }2 and coherence-ripple contribution of about 2 uW/cm\hat{ }2 to about 5 uW/cm\hat{ }2. In certain examples, regulated output voltage is about 1.2 V, quiescent current is about 150 nA, and cold-start voltage is about 180 mV. These values are provided as example performance metrics and should not be treated as limiting unless expressly recited in a claim.

In certain example sheet implementations operated at about 300 K in still air, total power density is between about 5 uW/cm\hat{ }2 and about 12 uW/cm\hat{ }2, with phonon-band contribution of about 3 uW/cm\hat{ }2 to about 7 uW/cm\hat{ }2 and coherence-ripple contribution of about 2 uW/cm\hat{ }2 to about 5 uW/cm\hat{ }2. In certain examples, regulated output voltage is about 1.2 V, quiescent current is about 150 nA, and cold-start voltage is about 180 mV. In certain further examples, the added phase noise to adjacent cavities is less than about 0.5 mrad, the decoherence-cancellation metric is about 99.999 percent for perturbations from about 10 kHz to about 10 THz, T2* at about 300 K is about 1.07 ms, and resonator Q at about 1 GHz is about 1.4×10\hat{ }5

In certain prophetic embodiments, the disclosed architecture may be adapted to additional application environments, including flexible systems, wearable systems, large-area functional skins, or other assemblies in which a continuously produced chi-lattice sheet may be beneficial. Such embodiments are presented as conceptually supported applications of the disclosed fabrication architecture and should not be understood as narrowing the core invention to any particular end-use market.

The foregoing examples are intended to illustrate operation and deployment of the disclosed fabrication architecture. They should not be interpreted as limiting the invention to any single substrate, material pair, path material, harvester type, electronics arrangement, production scale, or downstream use. The invention remains defined by the integrated roll-to-roll fabrication architecture and the load-bearing structural relations preserved thereby.

A person of ordinary skill in the art, having the benefit of the present disclosure, will understand that modifications may be made to the order of stations, local mechanics of transfer, coating chemistry, patterning implementation, integration approach, and metrology logic without departing from the disclosed invention, provided that the single-press phi-cascade transfer, the dual-phase relation equal to phi, the paired counter-helical path relation at phi/pi, and the metrology-driven process-control architecture remain preserved in the resulting fabrication platform and product.

What is claimed is:

1. A roll-to-roll method of fabricating a chi-lattice metamaterial sheet, comprising:
imprinting, in a single press cycle, a phi-pitch cascade pattern onto a moving web using a nanoimprint stamp having a working surface that defines at least three nested relief depths corresponding to a base pitch, a second pitch equal to the base pitch divided by phi, and a third pitch equal to the base pitch divided by phi squared;
forming first and second interpenetrating phases on the patterned web such that a volumetric ratio of the first and second interpenetrating phases is equal to phi;
forming paired counter-helical recognition paths in or on the patterned web, the paired counter-helical recognition paths being angularly offset by phi divided by pi; and
performing inline metrology on the patterned web and adjusting one or more process parameters based on the inline metrology.

2. The method of claim 1, wherein the moving web comprises a polymer web or a glass web.

3. The method of claim 1, wherein imprinting comprises applying a curable resist to the moving web and curing the curable resist while the moving web is in contact with the nanoimprint stamp.

4. The method of claim 3, wherein the curable resist is a ultraviolet-curable resist applied at a thickness between about 200 nanometers and about 500 nanometers.

5. The method of claim 1, wherein the nanoimprint stamp comprises a buried micro-channel network configured to equalize imprint pressure and a thermo-elastic compensation structure configured to reduce dimensional drift during operation.

6. The method of claim 1, wherein forming the first and second interpenetrating phases comprises conformal deposition by atomic-layer deposition.

7. The method of claim 6, wherein the first and second interpenetrating phases comprise hafnium oxide and silicon dioxide.

8. The method of claim 1, wherein forming the paired counter-helical recognition paths comprises mask-less digital lithography.

9. The method of claim 1, wherein each of the paired counter-helical recognition paths follows a helix having a radius equal to one-tenth of a lattice constant and a pitch equal to phi times the lattice constant.

10. The method of claim 1, wherein the paired counter-helical recognition paths are configured to cancel a first-order decoherence integral.

11. The method of claim 1, further comprising integrating one or more energy-harvesting elements at or relative to phi-lattice nodes.

12. The method of claim 11, wherein the one or more energy-harvesting elements comprise aluminum nitride trampoline membranes, niobium nitride meander inductors, or both.

13. The method of claim 11, further comprising integrating a switched-capacitor rectifier having a switching ratio equal to phi and a watchdog circuit configured to alter operation of the switched-capacitor rectifier in response to an imbalance condition.

14. The method of claim 1, wherein the inline metrology comprises multi-beam ellipsometry and a machine-learning correction engine configured to adjust one or more of imprint pressure, exposure dose, deposition cycle count, or patterning parameters based on measured phase-error data, and wherein the adjusting maintains continuous fabrication of the chi-lattice metamaterial sheet over extended web lengths while maintaining one or more of phase error, pitch fidelity, or volumetric-ratio fidelity within predetermined thresholds.

15. A nanoimprint stamp for roll-to-roll fabrication of a chi-lattice metamaterial sheet, comprising:
a working surface carrying at least three nested relief depths defining a phi-pitch cascade having a base pitch, a second pitch equal to the base pitch divided by phi, and a third pitch equal to the base pitch divided by phi squared;
a pressure-equalization structure configured to reduce imprint-pressure nonuniformity;
a thermo-elastic compensation structure configured to reduce dimensional drift during operation; and
a release surface treatment configured to facilitate repeated separation from a patterned web.

16. The nanoimprint stamp of claim 15, wherein the nanoimprint stamp is formed as a cylindrical roller.

17. The nanoimprint stamp of claim 15, wherein the pressure-equalization structure comprises a buried rectilinear micro-channel network, the thermo-elastic compensation structure comprises an Invar alloy frame, and the release surface treatment comprises a perfluoropolyether-based release coating.

18. A chi-lattice metamaterial sheet, comprising:
a triply periodic framework;
first and second interpenetrating phases arranged at a volumetric ratio equal to phi; and
paired counter-helical recognition paths angularly offset by phi divided by pi and configured to support first-order decoherence cancellation.

19. The chi-lattice metamaterial sheet of claim 18, further comprising one or more energy-harvesting elements disposed at or relative to phi-lattice nodes.

20. The chi-lattice metamaterial sheet of claim 19, wherein the one or more energy-harvesting elements comprise a first harvesting structure configured for phonon-band energy capture and a second harvesting structure configured for electromagnetic, inductive, or coherence-ripple energy capture.

21. The chi-lattice metamaterial sheet of claim 19, further comprising a switched-capacitor rectifier having a switching ratio equal to phi and a watchdog circuit configured to alter rectifier operation in response to an imbalance condition.

22. A roll-to-roll fabrication system, comprising:
a web-handling module configured to advance a moving web;
an imprint station configured to transfer a phi-pitch cascade pattern onto the moving web in a single press cycle;
a phase-formation station configured to form first and second interpenetrating phases at a volumetric ratio equal to phi;
a patterning station configured to form paired counter-helical recognition paths angularly offset by phi divided by pi;
an energy-harvester integration station; and
an inline metrology station configured to provide feedback to one or more of the imprint station, the phase-formation station, or the patterning station,
wherein the imprint station, the phase-formation station, the patterning station, the energy-harvester integration station, and the inline metrology station are arranged as an integrated continuous production line for fabrication of the chi-lattice metamaterial sheet.

23. A building assembly, comprising:
a support structure; and
a chi-lattice metamaterial sheet fabricated according to the method of claim 1 and coupled to the support structure,
wherein the chi-lattice metamaterial sheet includes one or more energy-harvesting elements configured to power at least one sensor, transmitter, or thermal-control circuit associated with the building assembly.

24. A non-transitory computer-readable medium storing instructions that, when executed by one or more processors, generate a fabrication description for a chi-lattice metamaterial sheet, the fabrication description defining:
a three-level phi-pitch cascade;
first and second interpenetrating phases at a volumetric ratio equal to phi; and
paired counter-helical paths at an angular offset equal to phi divided by pi,
and outputting a fabrication file for a nanoimprint, lithographic, or roll-to-roll patterning system, wherein the fabrication file comprises one or more of a GDSII file, an STL file, a digital-light-processing bitmap stream, an imprint-stamp pattern file, a lithographic mask file, or a toolpath file.

25. The non-transitory computer-readable medium of claim 24, wherein the instructions receive phase-error data from multi-beam ellipsometry and output, to a controller of the roll-to-roll fabrication system, at least one of (i) an imprint-pressure update, (ii) an exposure-dose update, or (iii) an atomic-layer-deposition cycle-count update.
